(19) United States
(12) Patent Application Publication
(10) Pub. No.: US 2024/0180011 A1
(43) Pub. Date: May 30, 2024

(54) DISPLAY DEVICE

(71) Applicant: Samsung Display Co., LTD., Yongin-si (KR)

(72) Inventor: JONGHYUN CHOI, Yongin-si (KR)

(21) Appl. No.: 18/236,495

(22) Filed: Aug. 22, 2023

(30) Foreign Application Priority Data
Nov. 29, 2022 (KR) 10-2022-0162998

(51) Int. Cl. H10K 59/88; G09G 3/3225; H10K 59/121; H10K 59/126; H10K 59/38; H10K 59/40; H10K 77/10

(52) U.S. Cl. CPC H10K 59/88; G09G 3/3225; H10K 59/1213; H10K 59/126; H10K 59/38; H10K 59/40; H10K 77/111; G09G 2300/0819; G09G 2300/0842; H10K 2102/311

(57) ABSTRACT

A display device includes a base layer, a first insulation layer disposed on the base layer, a line layer disposed on the first insulation layer, and where the line layer includes at least one selected from zinc (Zn), indium (In), gallium (Ga), tin (Sn), and titanium (Ti), and a line hole is defined in the line layer, a second insulation layer disposed on the line layer, where a line contact hole is defined in the second insulation layer, a valley electrode disposed on the second insulation layer and electrically connected with the line layer through the line contact hole, a third insulation layer disposed on the valley electrode, where a valley hole is defined in the third insulation layer, and an organic layer disposed on the third insulation layer. At least a portion of the organic layer is disposed in the valley hole to contact the valley electrode.

This application claims priority to Korean Patent Application No. 10-2022-0162998, filed on Nov. 29, 2022, and all the benefits accruing therefrom under 35 U.S.C. § 119, the content of which in its entirety is herein incorporated by reference.

### BACKGROUND

### 1. Field

The disclosure herein relates to a display device. More particularly, the disclosure herein relates to a display device with improved durability.

### 2. Description of the Related Art

A display device is activated by an electrical signal. The display device may include various layers such as a display panel that displays an image and an input sensing layer that senses an external input. The display device may include components that are electrically connected to each other by signal lines.

### SUMMARY

The disclosure provides a display device including a display panel with improved durability.

An embodiment of the invention provides a display device including: a base layer; a first insulation layer disposed on the base layer; a line layer disposed on the first insulation layer, where the line layer includes at least one selected from zinc (Zn), indium (In), gallium (Ga), tin (Sn) and titanium (Ti), and a line hole is defined in the line layer; a second insulation layer disposed on the line layer, where a line contact hole is defined in the second insulation layer; a valley electrode disposed on the second insulation layer and electrically connected with the line layer through the line contact hole: a third insulation layer disposed on the valley electrode, where a valley hole is defined in the third insulation layer; and an organic layer disposed on the third insulation layer. In such an embodiment, the line hole is defined through at least a portion of the line layer, and at least a portion of the organic layer is disposed in the valley hole to contact the valley electrode.

In an embodiment, the valley hole may overlap the valley electrode on a plane.

In an embodiment, the line hole may be spaced apart from the line contact hole on a plane.

In an embodiment, at least a portion of the first insulation layer, the second insulation layer, and the third insulation layer may be disposed in the line hole.

In an embodiment, the line hole may be provided in plurality.

In an embodiment, the valley hole may extend in a first horizontal direction, and a plurality of line holes may be symmetric in a second horizontal direction crossing the first horizontal direction with respect to the valley electrode.

In an embodiment, the line hole may overlap or be spaced apart from the valley electrode on a plane.

In an embodiment, the valley hole may extend in a first horizontal direction, and a distance from the valley electrode to the line hole in the first horizontal direction may be less than a width of the valley electrode in the first horizontal direction on a plane.

In an embodiment, a first insulation hole may be defined in the first insulation layer, and the first insulation hole may be defined to correspond to the line hole on a plane.

In an embodiment, a second insulation hole may be defined in the second insulation layer, and the second insulation hole may be defined to correspond to the line hole on a plane.

In an embodiment, each of the first insulation layer, the second insulation layer, and the third insulation layer may include at least one selected from an aluminum oxide, a titanium oxide, a silicon oxide, a silicon nitride, a silicon oxynitride, a zirconium oxide, and a hafnium oxide.

In an embodiment, the display device may further include a plurality of lower insulation layers disposed below the first insulation layer, and the plurality of lower insulation layers may include a first lower insulation layer, a second lower insulation layer, and a third lower insulation layer, which are sequentially laminated on the base layer.

In an embodiment, a lower insulation hole may be defined in the third lower insulation layer, and the line hole is defined to correspond to the lower insulation hole on a plane.

In an embodiment, the display device may further include a first transistor disposed on the first lower insulation layer, and the first transistor may include a silicon semiconductor pattern.

In an embodiment, the display device may further include a second transistor disposed on the first insulation layer, and the second transistor may include an oxide semiconductor pattern.

In an embodiment, the second transistor may include an oxide gate, and the oxide gate may be disposed on the second insulation layer.

In an embodiment, a material included in the oxide gate may be the same as a material included in the valley electrode.

In an embodiment, the oxide semiconductor pattern may include at least one selected from an indium-tin oxide (ITO), an indium-gallium-zinc oxide (IGZO), a zinc oxide (ZnO), an indium-zinc oxide (IZnO), a zinc-indium oxide (ZIO), an indium oxide (InO), a titanium oxide (TiO), an indium-zinc-tin oxide (IZTO), and a zinc-tin oxide (ZTO).

In an embodiment of the invention, a display device includes: a base layer: a plurality of insulation layers disposed on the base layer; and a line layer disposed on the insulation layer, where a line hole is defined in the line layer. In such an embodiment, the line layer includes at least one selected from zinc (Zn), indium (In), gallium (Ga), tin (Sn), and titanium (Ti), the line hole is defined by an inner surface of the line layer, and a portion of an insulation layer among the plurality of insulation layers is disposed in the line hole. In an embodiment, The line hole may be defined through at least a portion of the line layer.

### BRIEF DESCRIPTION OF THE DRAWINGS

The above and other features of the invention will become more apparent by describing in further detail embodiments thereof with reference to the accompanying drawings, in which:

FIG. 1A is a perspective view illustrating a display device in an unfolded state according to an embodiment of the invention;

FIG. 1B is a perspective view illustrating the display device in a folded state according to an embodiment of the invention;

FIG. 2 is a cross-sectional view illustrating the display device according to an embodiment of the invention;

FIG. 3 is a block diagram representing the display device according to an embodiment of the invention;

FIG. 4 is an equivalent circuit diagram of a pixel according to an embodiment of the invention;

FIG. 5 is a plan view illustrating pixels adjacent to each other according to an embodiment of the invention;

FIG. 6 is a cross-sectional view illustrating a display module according to an embodiment of the invention;

FIGS. 7A and 7B are plan views illustrating some of components contained in a display module according to embodiments of the invention; and

FIGS. 8A to 8D are cross-sectional views illustrating some of the components contained in the display module according to embodiments of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. In this specification, it will be understood that when one component (or region, layer, portion) is referred to as being ‘on’, ‘connected to’, or ‘coupled to’ another component, it can be directly disposed/connected/coupled on/to the one component, or an intervening third component may also be present.

Like reference numerals refer to like elements throughout. Also, in the figures, the thickness, ratio, and dimensions of components are exaggerated for clarity of illustration.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term and/or includes any and all combinations of one or more of the associated listed items.

It will be understood that although the terms such as ‘first’ and ‘second’ are used herein to describe various elements, these elements should not be limited by these terms. The terms are only used to distinguish one component from other components. For example, a first element referred to as a first element in one embodiment can be referred to as a second element in another embodiment without departing from the scope of the appended claims. The terms of a singular form may include plural forms unless referred to the contrary.

Also, spatially relative terms, such as “below”, “lower”, “above”, and “upper”, may be used herein for ease of description to describe an element and/or a feature's relationship to another element(s) and/or feature(s) as illustrated in the drawings. The terms may be a relative concept and described with respect to directions expressed in the drawings.

The meaning of ‘include’ or ‘comprise’ specifies a property, a fixed number, a step, an operation, an element, a component or a combination thereof, but does not exclude other properties, fixed numbers, steps, operations, elements, components or combinations thereof.

Unless otherwise defined, all terms (including technical and scientific terms) used herein have the same meaning as generally understood by those skilled in the art. Terms as defined in a commonly used dictionary should be construed as having the same meaning as in an associated technical context, and unless defined apparently in the description, the terms are not ideally or excessively construed as having formal meaning.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings.

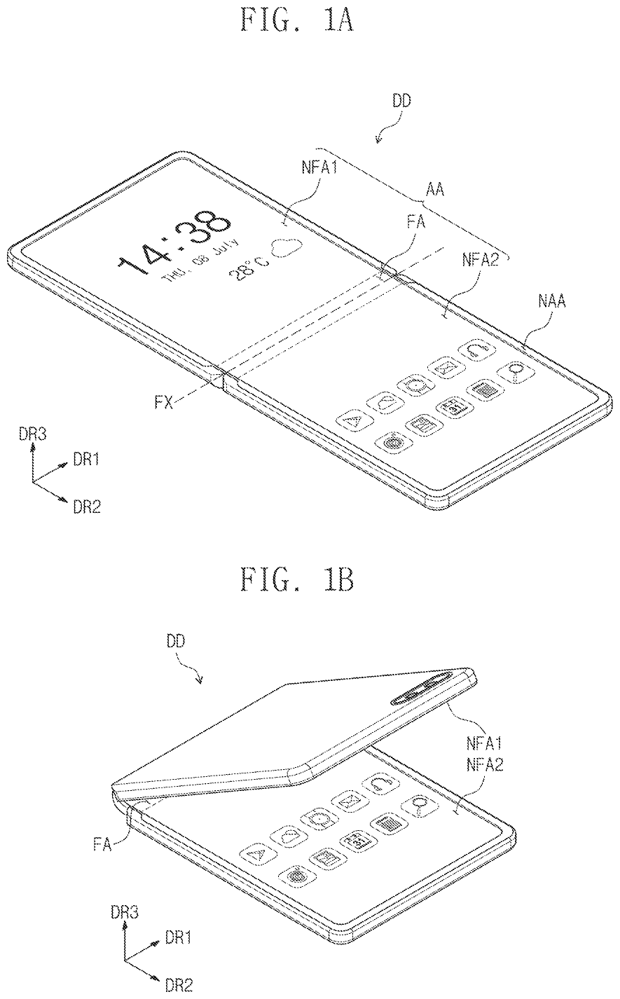

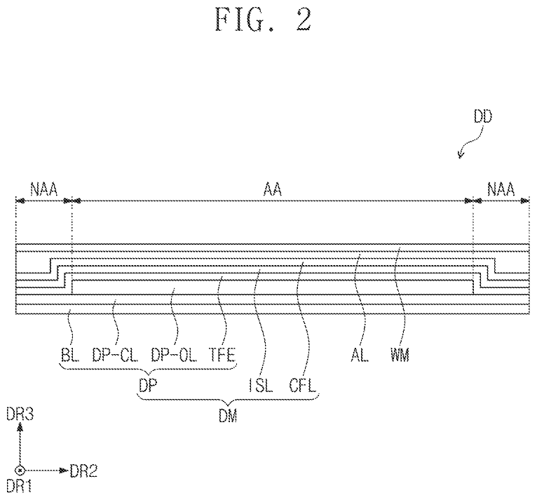

FIG. 1A is a perspective view illustrating a display device in an unfolded state according to an embodiment of the invention. FIG. 1B is a perspective view illustrating the display device in a folded state according to an embodiment of the invention.

Referring to FIGS. 1A and 1B, a display device DD according to an embodiment of the invention may be activated by an electrical signal. In an embodiment, for example, the display device DD may be a mobile phone, a tablet computer, a navigation unit for a vehicle, a game console, or a wearable device. However, the embodiment of the invention is not limited thereto. FIG. 1A illustrates an embodiment where the display device DD is a mobile phone as an example.

The display device DD may display an image through an active area AA and sense an external input. When the display device DD is in the unfolded (spread) state, the active area AA may be on a plane defined by a first direction DR1 and a second direction DR2. A direction of a thickness of the display device DD may be defined as a third direction DR3 perpendicular to each of the first and second directions DR1 and DR2. Thus, a front surface (or a top surface) and a rear surface (or a bottom surface) of members of the display device DD may be defined with respect to the third direction DR3.

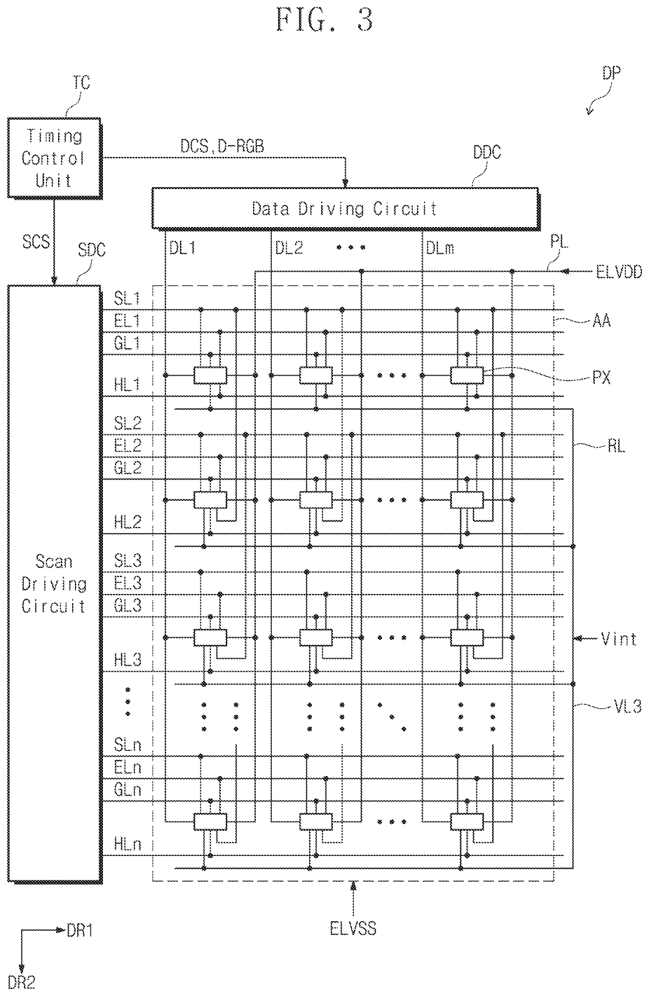

A peripheral area NAA may surround at least a portion of the active area AA. The peripheral area NAA may be an area printed on a window WM (refer to FIG. 2) that will be described later or an area defined by a bezel pattern having a tape shape. The bezel pattern may include a predetermined color.

Although FIG. 1A shows an embodiment where the peripheral area NAA surrounds four side surfaces of the active area AA as an example, the embodiment of the invention is not limited thereto. In an alternative embodiment, for example, the peripheral area NAA may not be disposed on at least one side surface of the active area AA, or the peripheral area NAA may be omitted.

The display device DD according to an embodiment of the invention may include a folding area FA and non-folding areas NFA1 and NFA2 spaced apart from each other in the second direction DR2 with the folding area FA therebetween. The folding area FA may be folded with respect to an imaginary folding axis FX extending in the first direction DR1.

When the display device DD is folded or in a folded state, the first non-folding area NFA1 and the second non-folding area NFA2 may face each other. Thus, the active area AA may not be exposed to the outside in a completely folded state, which may be referred to as in-folding. However, this is merely illustrative, and the embodiment of the invention is not limited to the operation of the display device DD.

For example, in an embodiment of the invention, when the display device DD is folded, the first non-folding area NFA1 and the second non-folding area NFA2 may be opposing to each other in a state in which the active area AA is exposed to the outside. This may be referred to as out-folding.

The display device DD may perform only one operation of the in-folding or the out-folding. Alternatively, the display device DD may perform all of the in-folding operation or the out-folding operation. In this case, the same area of the display device DD, e.g., the folding area AA, may be in-folded and out-folded. Alternatively, one area of the display device DD may be in-folded, and another area thereof may be out-folded.

Although FIGS. 1A and 1B show an embodiment where a single folding area FA and two non-folding areas NFA1 and NFA2 are defined in the display device DD as an example, the embodiment of the invention is not limited to the number of each of the folding area and the non-folding area. In an alternative embodiment, for example, the display device DD may include two or more plurality of non-folding areas and a plurality of folding areas disposed between the non-folding areas that are adjacent to each other.

Although FIGS. 1A and 1B show an embodiment where the folding axis FX is parallel to a minor axis extending in the first direction DR1 in the display device DD as an example, the embodiment of the invention is not limited thereto. In an alternative embodiment, for example, the folding axis FX may extend in parallel to a major axis extending in the second direction DR2 in the display device DD. In such an embodiment, the folding area FA, the first non-folding area NFA1, and the second non-folding area NFA2 may be sequentially arranged in the first direction DR1.

The display device DD may have an appearance defined as a case and a window WM (refer to FIG. 2). The case may be provided in plurality according to the number of the non-folding areas and further include a hinge structure connecting the cases and overlapping the folding area to allow the display device to be easily folded.

The display device DD may sense an external input applied from the outside. The external input may include various types of inputs provided from the outside of the display device DD. In an embodiment, for example, the external input may include a contact generated (or a touch) by a portion of a user's body such as hands and an external input (e.g., hovering) that is applied by being adjacent to the display device DD or being disposed adjacent by a predetermined distance thereto. Also, the external input may include various types of inputs such as force, pressure, temperature, and light.

FIG. 2 is a cross-sectional view illustrating the display device according to an embodiment of the invention.

Referring to FIG. 2, an embodiment of the display device DD may include a window WM and a display module DM. The display module DM may include a display panel DP, an input sensing layer ISL, and a filter layer CFL. The window WM and the display module DM may be coupled to each other through an adhesive layer AL disposed between the window WM and the display module DM. The adhesive layer AL may include at least one selected from an optically clear adhesive, an optically clear adhesive resin, and a pressure sensitive adhesive (PSA).

The window WM has a front surface that defines the active area AA of the display device DD. The window WM may include an optically clear insulating material. In an embodiment, for example, the window WM may include glass or plastic. The window WM may have a multi-layer structure or a single-layer structure. In an embodiment, for example, the window WM may include a plurality of plastic films coupled to each other by an adhesive or a glass substrate and a plastic film, which are coupled to each other by an adhesive.

The display panel DP may be a component that substantially generates an image. The display panel DP may be a light emitting display panel. In an embodiment, for example, the display panel DP may be an organic light emitting display panel, an inorganic light emitting display panel, an organic-inorganic light emitting display panel, a quantum dot display panel, a micro-light emitting diode (LED) display panel, or a nano-LED display panel.

The display panel DP may include a base layer BL, a circuit layer DP-CL, an element layer DP-OL, and an encapsulation layer TFE.

The base layer BL may be a basal layer on which other components of the display panel DP are disposed. The base layer BL may include or be made of a flexible material.

The circuit layer DP-CL is disposed on the base layer BL. The circuit layer DP-CL includes at least one insulation layer and a circuit element. The insulation layer includes at least one inorganic layer and at least one organic layer. The circuit element may include a pixel driving circuit included in each of a plurality of pixels for displaying an image. The element layer DP-OL may include a light emitting element connected to the circuit layer DP-CL.

The encapsulation layer TFE seals the element layer DP-OL. The encapsulation layer TFE may include at least one organic layer and inorganic layers that seal the organic layer. The inorganic layer may include an inorganic material and protect the element layer DP-OL from moisture or oxygen.

In an embodiment, the inorganic layer may include a silicon nitride layer, a silicon oxynitride layer, a silicon oxide layer, a titanium oxide layer, or an aluminum oxide layer, but the embodiment of the invention is not limited thereto. The organic layer may include an organic material and protect the element layer DP-OL from foreign substances such as dust particles. In an embodiment, the organic layer may include an acryl-based organic material, but the embodiment of the invention is not limited thereto.

The input sensing layer ISL may be disposed on the display panel DP. The input sensing layer ISL may sense an external input applied through the window WM. The external input may be an input of a user. In an embodiment, for example, the input of the user may include various types of external inputs such as a portion of a user's body, light, heat, a pen or pressure.

In an embodiment, the input sensing layer ISL may be disposed on the display panel DP through a continuous process. In such an embodiment, the input sensing layer ISL is directly disposed on the display panel DP. In an embodiment, for example, a feature of being “directly disposed” may represent that a third component is not disposed between the input sensing layer ISL and the display panel DP. That is, an additional adhesive member may not be disposed between the input sensing layer ISL and the display panel DP. Alternatively, the input sensing layer ISL and the display panel DP may be coupled to each other through an adhesive member. The adhesive member may include a typical adhesive or a typical sticking agent.

The filter layer CFL may be disposed on the input sensing layer ISL. The filter layer CFL may include a reflection preventing layer that reduces a reflectance of external light incident from the outside of the display device DD. However, the embodiment of the invention is not limited thereto. In an embodiment, for example, the filter layer CFL may include a color filter capable of selectively transmitting light corresponding to light provided from the display panel DP.

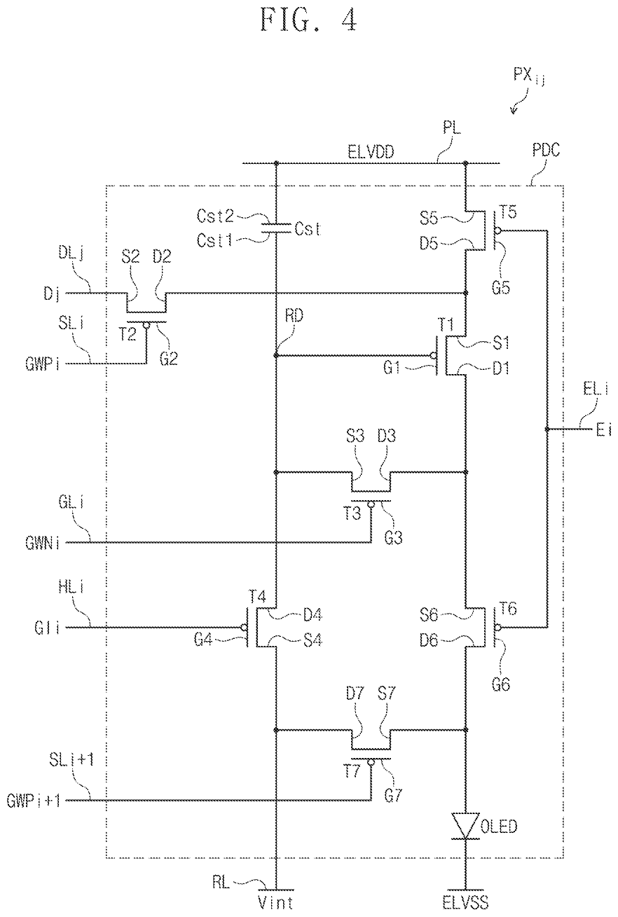

FIG. 3 is a block diagram representing the display device according to an embodiment of the invention.

In an embodiment, the display panel DP may include a timing control unit (or a timing controller or circuit) TC, a scan driving circuit SDC, a data driving circuit DDC, and pixels PX overlapping the active area AA. In an embodiment, for example, the display panel DP may be an organic light emitting display panel among light emitting display panels.

The timing control unit TC receives input image signals and converts a data format of the input image signals to be matched with specifications of an interface with the scan driving circuit SDC, thereby generating the image data D-RGB. The timing control unit TC outputs the image data D-RGB and control signals DCS and SCS for other circuits or drivers.

The scan driving circuit SDC receives a scan control signal SCS from the timing control unit TC. The scan control signal SCS may include a vertical start signal that starts an operation of the scan driving circuit SDC and a clock signal that determines an output time of signals. The scan driving circuit SDC generates a plurality of scan signals and output the generated scan signals to corresponding signal lines SL1 to SLn and GL1 to GLn. Here, n is a natural number greater than 1. Also, the scan driving circuit SDC generates a plurality of light emitting control signals in response to the scan control signal SCS and outputs the generated light emitting control signals to corresponding signal lines EL1 to ELn.

Although, in an embodiment, the plurality of scan signals and the plurality of light emitting control signals may be outputted from a single scan driving circuit SDC as shown in FIG. 3, the embodiment of the invention is not limited thereto. In an alternative embodiment of the invention, a plurality of scan driving circuits may separately generate scan signals and then output the scan signals, and may separately generate a plurality of light emitting control signals and then output the light emitting control signals. Also, in an embodiment of the invention, a driving circuit for generating and outputting a plurality of scan signals and a driving circuit for generating and outputting a plurality of light emitting control signals may be separately distinguished.

The data driving circuit DDC receives a data control signal DCS and image data D-RGB from the timing control unit TC. The data driving circuit DDC converts the image data D-RGB into data signals and outputs the data signals to a plurality of data lines DL1 to DLm that will be described later. Here, m is a natural number greater than 1. The data signals are analog voltages corresponding to gray values of the image data D-RGB.

The display panel DP includes scan lines SL1 to SLn of a first group, scan lines GL1 to GLn of a second group, scan lines HL1 to HLn of a third group, light emitting lines EL1 to ELn, data lines DLI to DLm, a first voltage line PL, a second voltage line RL, and a plurality of pixels PX. The scan lines SL1 to SLn of the first group, the scan lines GL1 to GLn of the second group, the scan lines HL1 to HLn of the third group, and the light emitting lines EL1 to ELn may each extend in the first direction and be arranged in the second direction DR2 crossing the first direction DR1.

The plurality of data lines DLI to DLm cross, in an insulating manner, the scan lines SL1 to SLn of the first group, the scan lines GL1 to GLn of the second group, the scan lines HL1 to HLn of the third group, and the light emitting lines ELI to ELn. Each of the plurality of pixels PX is connected to corresponding signal lines among the signal lines, respectively. A connection relationship between the pixels PX and the signal lines may be changed or modified according to a configuration of the driving circuit of the pixels PX.

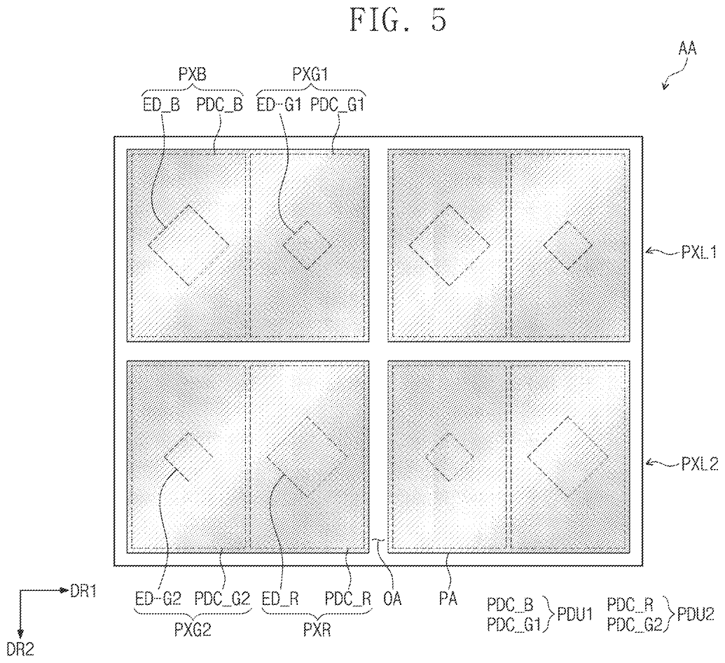

The first voltage line PL receives a first power voltage ELVDD. The second voltage line RL receives an initialization voltage Vint. The initialization voltage Vint has a voltage level less than that of the first power voltage ELVDD. A second power voltage ELVSS is applied to a light emitting element OLED (refer to FIG. 4). The second power voltage ELVSS has a voltage level less than that of the first power voltage ELVDD.

The plurality of pixels PX may include a plurality of groups that generate different colors from each other. In an embodiment, for example, the pixels PX may include red pixels that generates (or emits) red light, green pixels that generates green light, and blue pixels that generates blue light. A light emitting element of the red pixel, a light emitting element of the green pixel, and a light emitting element of the blue pixel may include light emitting layers including or made of different materials from each other.

A pixel circuit PDC (refer to FIG. 4) included in each of the pixels PX may include a plurality of transistors, a capacitor electrically connected to the transistor, and the above-described conductive patterns. At least one selected from the scan driving circuit SDC and the data driving circuit DDC may include a plurality of transistors provided through a same process as the pixel circuit PDC (refer to FIG. 4).

The signal lines, the plurality of pixels PX, the scan driving circuit SDC, and the data driving circuit DDC, which are described above, may be provided on the base layer BL (refer to FIG. 2) by performing a photolithography process a plurality of times. A plurality of insulation layers may be provided on the base layer BL (refer to FIG. 2) by performing a deposition process or a coating process a plurality of times. The plurality of insulation layers may be thin-films disposed in correspondence to the plurality of pixels PX, and some of the plurality of insulation layers may include an insulation pattern overlapping only a specific conductive pattern. The insulation layers include an organic layer and/or an inorganic layer.

FIG. 4 is an equivalent circuit diagram of a pixel according to an embodiment of the invention.

In FIG. 4, an embodiment of a pixel PXij connected to an i-th scan line SLi among the scan lines SL1 to SLn of the first group and connected to a j-th data line DLj among the plurality of data lines DLI to DLm is illustrated as an example. Here, i is a natural number greater than or equal to 1 and less than or equal to n, and j is a natural number greater than or equal to 1 and less than or equal to m.

In an embodiment, the pixel circuit PDC may include first to seventh transistors T1 to T7, a capacitor Cst, and the above-described conductive patterns. In an embodiment, each of the first transistor T1, the second transistor T2, and the fifth to seventh transistors T5 to T7 is a p-type transistor, and each of the third transistor T3 and the fourth transistor T4 is an n-type transistor. However, the embodiment of the invention is not limited thereto. In an alternative embodiment, for example, each of the first to seventh transistors TI to T7 may be realized by one of the p-type transistor and the n-type transistor. Also, in another alternative embodiment of the invention, at least one selected from the first to seventh transistors TI to T7 may be omitted.

In an embodiment, the first transistor T1 may be a driving transistor, and the second transistor T2 may be a switching transistor. The capacitor Cst is connected between the first voltage line PL that receives the first power voltage ELVDD and a reference node RD. The capacitor Cst includes a first capacitor electrode Cst1 connected to the reference node RD and a second capacitor electrode Cst2 connected to the first voltage line PL.

The first transistor T1 is connected between the first voltage line PL and one electrode of the light emitting element OLED. A source S1 of the first transistor T1 is electrically connected to the first voltage line PL. Another transistor may be disposed or may not be disposed between the first voltage line PL and the source S1 of the first transistor T1.

A drain D1 of the first transistor T1 is electrically connected to a first electrode AE of the light emitting element OLED. Another transistor may be disposed or may not be disposed between the drain D1 of the first transistor T1 and the first electrode AE of the light emitting element OLED. A gate G1 of the first transistor T1 is electrically connected to the reference node RD.

The second transistor T2 is connected between the j-th data line DLj and the source SI of the first transistor T1. A source S2 of the second transistor T2 is electrically connected to the j-th data line DLj, and a drain D2 of the second transistor T2 is electrically connected to the source SI of the first transistor T1. In the embodiment, a gate G2 of the second transistor T2 may be electrically connected to the i-th scan line SLi of the first group.

The third transistor T3 is connected between the reference node RD and the drain D1 of the first transistor T1. A drain D3 of the third transistor T3 is electrically connected to the drain D1 of the first transistor T1, and a source S3 of the third transistor T3 is electrically connected to the reference node RD. In an embodiment, a gate G3 of the third transistor T3 may be electrically connected to an i-th scan line GLi of the second group.

The fourth transistor T4 is connected between the reference node RD and the second voltage line RL that receives the initialization voltage Vint. A drain D4 of the fourth transistor T4 is electrically connected to the reference node RD, and a source S4 of the fourth transistor T4 is electrically connected to the second voltage line RL. In an embodiment, a gate G4 of the fourth transistor T4 may be electrically connected to an i-th scan line HLi of the third group.

The fifth transistor T5 is connected between the first voltage line PL and the source SI of the first transistor T1. A source S5 of the fifth transistor T5 is electrically connected to the first voltage line PL, and a drain D5 of the fifth transistor T5 is electrically connected to the source SI of the first transistor T1. A gate G5 of the fifth transistor T5 may be electrically connected to an i-th light emitting line Eli.

The sixth transistor T6 is connected between the drain D1 of the first transistor T1 and the light emitting element OLED. A source S6 of the sixth transistor T6 is electrically connected to the drain D1 of the first transistor T1, and a drain D6 of the sixth transistor T6 is electrically connected to the first electrode AE of the light emitting element OLED. A gate G6 of the sixth transistor T6 may be electrically connected to the i-th light emitting line Eli.

The seventh transistor T7 is connected between the drain D6 of the sixth transistor T6 and the second voltage line RL. A source S7 of the seventh transistor T7 is electrically connected to the drain D6 of the sixth transistor T6, and a drain D7 of the seventh transistor T7 is electrically connected to the second voltage line RL. A gate G7 of the seventh transistor T7 may be electrically connected to an (i+1)-th scan line SLi+1 of the first group.

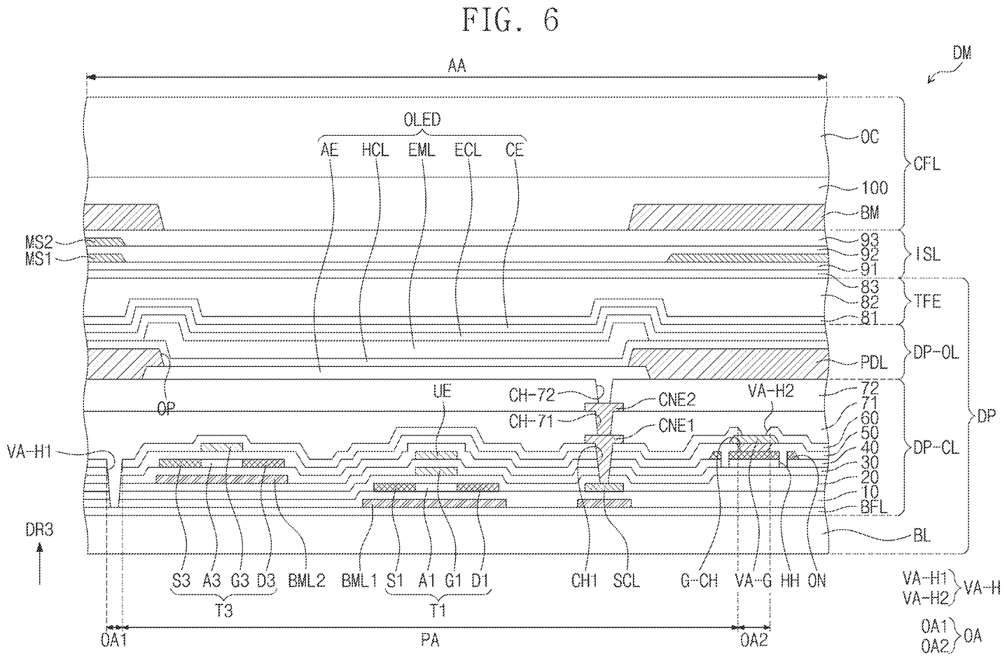

FIG. 5 is a plan view illustrating pixels disposed adjacent to each other according to an embodiment of the invention. The same or similar components as those described above with reference to FIGS. 1A to 4 will be designated by the same or similar reference numerals, respectively, and any repetitive detailed description thereof will be omitted.

In FIG. 5, eight pixels arranged in the first direction DR1 and the second direction DR2 among the pixels PX described in FIG. 3 are shown. The pixels may have a structure of being repeatedly arranged in a first pixel row PXL1 under a predetermined rule. In an embodiment, for example, the first pixel row PXL1 may include a first pixel PXB and a first second pixel (hereinafter, will be referred to as “second-1 pixel”) PXG1.

A second pixel row PXL2 may be spaced apart from the first pixel row PXL1 in the second direction DR2, and the pixels may have a structure of being repeatedly arranged in the second pixel row PXL2 under a predetermined rule. In an embodiment, for example, the second pixel row PXL2 may include a second second pixel (hereinafter, will be referred to as “second-2 pixel”) PXG2 and a third pixel PXR.

The first pixel row PXL1 and the second pixel row PXL2 may each extend in the first direction DR1 and be alternately arranged in the second direction DR2. Hereinafter, any repetitive detailed description of the pixels arranged in a same pixel row will be omitted.

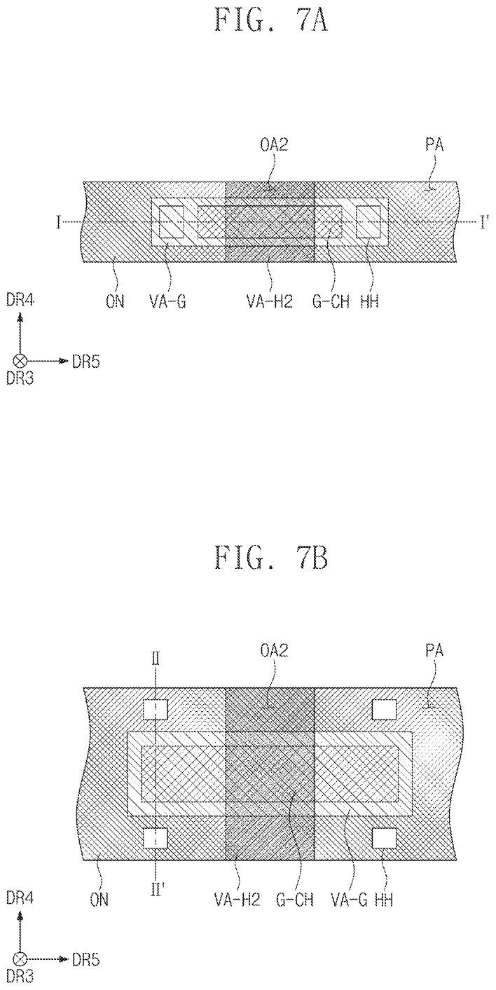

Referring to FIG. 5, the first pixel PXB of the first pixel row PXL1 may include a first pixel circuit PDC_B and a first light emitting element ED_B connected to the first pixel circuit PDC_B. The first light emitting element ED_B may have a planar shape corresponding to that of an opening OP (refer to FIG. 6) of a pixel defining layer PDL (refer to FIG. 6). This feature may be applied in the same manner to a planar shape of each of the light emitting elements that will be described below. The first pixel circuit PDC_B may correspond to the pixel circuit PDC described in FIG. 4.

The second-1 pixel PXG1 of the first pixel row PXL1 may be spaced apart from the first pixel PXB in the first direction DR1. The second-1 pixel PXG1 may include a first second pixel circuit (hereinafter, will be referred to as “second-1 pixel circuit”) PDC_G1 and a first second light emitting element (hereinafter, will be referred to as “second-1 light emitting element”) ED_G1 connected to the second-1 pixel circuit PDC_G1.

In an embodiment, a first pixel circuit unit PDU1 may include the first pixel circuit PDC_B and the second-1 pixel circuit PDC_G1. The first pixel circuit PDC_B and the second-1 pixel circuit PDC_G1 may be adjacent to each other in the first direction DR1. The conductive patterns disposed in the first pixel circuit unit PDU1 of the first pixel row PXL1, e.g., the conductive patterns extending in the first direction DR1 among the scan lines, the data lines, and the power lines, which are described in FIGS. 3 and 4, may be disposed in the first pixel circuit unit PDU1 in common.

The second-2 pixel PXG2 of the second pixel row PXL2 may include a second second pixel circuit (hereinafter, will be referred to as “second-2 pixel circuit”) PDC_G2 and a second second light emitting element (hereinafter, will be referred to as “second-2 light emitting element”) ED_G2 connected to the second-2 pixel circuit PDC_G2.

The third pixel PXR of the second pixel row PXL2 may include a third pixel circuit PDC_R and a third light emitting element ED_R connected to the third pixel circuit PDC_R. The third pixel PXR may be spaced apart from the second-2 pixel PXG2 in the first direction DR1.

In an embodiment, a second pixel circuit unit PDU2 may include the second-2 pixel circuit PDC_G2 and the third pixel circuit PDC_R. The second-2 pixel circuit PDC_G2 and the third pixel circuit PDC_R may be adjacent to each other in the first direction DR1. The conductive patterns disposed in the second pixel circuit unit PDU2 of the second pixel row PXL2, e.g., the conductive patterns extending in the first direction DR1 among the scan lines, the data lines, and the power lines, which are described in FIGS. 3 and 4, may be disposed in the second pixel circuit unit PDU2 in common. Also, the conductive patterns extending in the second direction DR2 among the conductive patterns may be disposed in the first pixel circuit unit PDU1 and the second pixel circuit unit PDU2 in common.

According to an embodiment, the first pixel PXB may generate blue light, each of the second-1 pixel PXG1 and the second-2 pixel PXG2 may generate green light, and the third pixel PXR may generate red light. However, this is merely illustrative, and the embodiment of the invention is not limited thereto. In an alternative embodiment, for example, three or more pixel circuits may be disposed in one pixel circuit unit.

According to an embodiment, the active area AA may include a plurality of pixel areas PA and a boundary area OA. The boundary area OA may surround the plurality of pixel areas PA. The boundary area OA may surround the corresponding first pixel circuit unit PDU1. Thus, the boundary area OA may define a boundary between the first pixel circuit units PDU1 adjacent to each other in the first direction DR1. The boundary area OA may surround the corresponding second pixel circuit unit PDU2. Thus, the boundary area OA may define a boundary between the second pixel circuit units PDU2 adjacent to each other in the first direction DR1.

FIG. 6 is a cross-sectional view illustrating the display module according to an embodiment of the invention.

FIG. 6 illustrates a cross-section of a portion corresponding to the first transistor T1 and the third transistor T3 among the first to seventh transistors TI to T7 described in FIG. 4.

In an embodiment, as shown in FIG. 6, the display module DM may include a display panel DP, an input sensing layer ISL, and a filter layer CFL. The display panel DP may include a base layer BL, a circuit layer DP-CL, an element layer DP-OL, and an encapsulation layer TFE.

The display panel DP may further include functional layers such as an anti-reflection layer or a refractive index adjusting layer. The circuit layer DP-CL includes at least a plurality of insulation layers and the pixel circuit PDC (refer to FIG. 4). In an embodiment, the insulation layers may include an organic layer and/or an inorganic layer.

The base layer BL may include a synthetic resin film. The synthetic resin layer may include a thermosetting resin. In an embodiment, the synthetic resin layer may be a polyimide-based resin layer, but the embodiment of the invention is not limited to the material of the synthetic resin layer. The synthetic resin layer may include at least one selected from an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. In an embodiment, the base layer BL may be a glass substrate, a metal substrate, or an organic/inorganic composite substrate.

The base layer BL may have a shape in which organic layers and inorganic layers are alternately laminated. In an embodiment, for example, the base layer BL may have a structure in which a first organic layer containing (or including) polyimide, a first inorganic layer disposed on the first organic layer, a second organic layer containing polyimide and disposed on the first inorganic layer, and a second inorganic layer disposed on the second organic layer are alternately laminated. However, the embodiment of the invention is not limited thereto.

The circuit layer DP-CL may include a buffer layer BFL, a plurality of insulation layers 10 to 60 and 71 to 72, and conductive patterns contained in (or that collectively define) the transistors.

An insulation layer, a semiconductor layer, and a conductive layer may be provided in the circuit layer DP-CL by a method such as coating and deposition. Thereafter, the insulation layer, the semiconductor layer, and the conductive layer may be selectively patterned by a photolithography method. Through this method, the semiconductor pattern, the conductive pattern, and the signal lines may be provided.

The circuit layer DP-CL may include the buffer layer BFL, the plurality of insulation layers 10 to 60 and 71 to 72, electrodes contained in the capacitor Cst (refer to FIG. 4), electrodes contained in the transistors TI to T7 (refer to FIG. 3), and the above-described conductive patterns.

The buffer layer BFL may contact (or be disposed directly on) the base layer BL. The buffer layer BFL may include an inorganic material. In an embodiment, for example, the buffer layer BFL may include at least one selected from an aluminum oxide, a titanium oxide, a silicon oxide, a silicon nitride, a silicon oxynitride, a zirconium oxide, and a hafnium oxide. The buffer layer BFL may have a multi-layer structure. The buffer layer BFL may reduce surface energy of the base layer BL so that the pixel PX is stably provided on the base layer BL.

A first light shielding pattern BML1 may be disposed on the buffer layer BFL. The first light shielding pattern BML1 may overlap a semiconductor pattern of the first transistor T1. The first light shielding pattern BML1 may be disposed directly on the base layer BL in an embodiment where the buffer layer BFL is omitted. The first light shielding pattern BML1 may include molybdenum.

The first light shielding pattern BML1 may have a shielding function. The first light shielding pattern BML1 may prevent electric potential caused by a polarization phenomenon between the insulation layers disposed on the first light shielding pattern BML1 from affecting the first to seventh transistors T1 to T7.

A first lower insulation layer 10 may coves the first light shielding pattern BML1 and be disposed on the buffer layer BFL. The first lower insulation layer 10 may include an inorganic material. In an embodiment, for example, the first lower insulation layer 10 may include at least one selected from an aluminum oxide, a titanium oxide, a silicon oxide, a silicon nitride, a silicon oxynitride, a zirconium oxide, and a hafnium oxide. The first lower insulation layer 10 may have a multi-layer structure.

The semiconductor pattern of the first transistor T1 may be disposed on the first lower insulation layer 10. The semiconductor pattern may include a silicon semiconductor. The semiconductor pattern may include polysilicon. However, the embodiment of the invention is not limited thereto. In an embodiment, for example, the semiconductor pattern may include amorphous silicon. In an embodiment, for example, the semiconductor pattern may include low-temperature polycrystalline silicon (LTPS).

A source S1, an active A1 and a drain D1 of the first transistor T1 may be provided from (or defined by portions of) the semiconductor pattern. The source S1 and the drain D1 of the first transistor T1 may be spaced apart from each other with the active A1 therebetween.

FIG. 6 merely illustrates a portion of the semiconductor pattern, and the semiconductor pattern may be further disposed on another area of the pixel PXij (refer to FIG. 4). The semiconductor pattern has an electrical property that is different according to whether doped or not. The semiconductor pattern may include a doped area and a non-doped area. The doped area may be doped with an n-type dopant or a p-type dopant. A p-type transistor includes a doped area that is doped with the p-type dopant.

A connection signal line SCL may be disposed on the first lower insulation layer 10. The connection signal line SCL may be connected to the sixth transistor T6 (refer to FIG. 4) on a plane. Here, the term “on a plane” may mean in a plan view or when viewed in the third direction DR3. In an embodiment, the first light shielding pattern BML1 may be further provided to overlap the connection signal line SCL.

A second lower insulation layer 20 may cover the semiconductor pattern and the connection signal line SCL and be disposed on the first lower insulation layer 10. The second lower insulation layer 20 may include at least one selected from an aluminum oxide, a titanium oxide, a silicon oxide, a silicon nitride, a silicon oxynitride, a zirconium oxide, and a hafnium oxide.

The gate G1 of the first transistor T1 may be disposed on the second lower insulation layer 20. The gate G1 may be a portion of a metal pattern. The gate G1 of the first transistor T1 overlaps the active A1 of the first transistor T1. The gate G1 of the first transistor T1 may serve as a mask in a process of doping the semiconductor pattern.

A third lower insulation layer 30 may cover the gate G1 and be disposed on the second lower insulation layer 20. The third lower insulation layer 30 may include at least one selected from an aluminum oxide, a titanium oxide, a silicon oxide, a silicon nitride, a silicon oxynitride, a zirconium oxide, and a hafnium oxide.

An upper electrode UE may be disposed on the third lower insulation layer 30. The upper electrode UE may overlap the gate G1. The upper electrode UE may be a portion of a metal pattern or a portion of a doped semiconductor pattern. The capacitor Cst (refer to FIG. 4) may be defined by a portion of the gate G1 and the upper electrode UE overlapping the portion of the gate G1. In an embodiment, the upper electrode UE may be omitted.

A second light shielding pattern BML2 may be disposed on the third lower insulation layer 30. The second light shielding pattern BML2 may overlap a semiconductor pattern of the third transistor T3. The second light shielding pattern BML2 may include molybdenum. According to an embodiment, the second light shielding pattern BML2 may be omitted.

In an embodiment, the third lower insulation layer 30 may be disposed over the entire active area AA as shown in FIG. 6, but the embodiment of the invention is not limited thereto. In an alternative embodiment, for example, the third lower insulation layer 30 may be replaced by an insulation pattern. In such an embodiment, the upper electrode UE is disposed on the insulation pattern. The upper electrode UE may serve as a mask for providing the insulation pattern from the third lower insulation layer 30.

A first insulation layer 40 may cover the upper electrode UE and the second light shielding pattern BML2 and be disposed on the third lower insulation layer 30. The first insulation layer 40 may include at least one selected from an aluminum oxide, a titanium oxide, a silicon oxide, a silicon nitride, a silicon oxynitride, a zirconium oxide, and a hafnium oxide.

The source S2, S5, S6, and S7 and the drain D2, D5, D6, and D7 of the second, fifth, sixth, and seventh transistors T2, T5, T6, and T7 that are described in FIG. 4 may be provided by a same process as the source SI and the drain D1 of the first transistor T1, and the gate G2, G5, G6, and G7 of the second, fifth, sixth, and seventh transistors T2, T5, T6, and T7 may be provided by a same process as the gate G1 of the first transistor T1. The patterns provided by a same process may be disposed in (or directly on) a same layer as each other.

The semiconductor pattern of the third transistor T2 may be disposed on the first insulation layer 40. The semiconductor pattern may include a metal oxide. An oxide semiconductor may include a crystalline or amorphous oxide semiconductor.

In an embodiment, for example, the oxide semiconductor may include one selected from an indium-tin oxide (ITO), an indium-gallium-zinc oxide (IGZO), an zinc oxide (ZnO), an indium-zinc oxide (IZnO), a zinc-indium oxide (ZIO), an indium oxide (InO), a titanium oxide (TiO), an indium-zinc-tin oxide (IZTO), and a zinc-tin oxide (ZTO).

A source S3, an active A3 and a drain D3 of the third transistor T3 may be provided from the semiconductor pattern. The source S3 and the drain D3 include metal reduced from the metal oxide semiconductor. Each of the source S3 and the drain D3 may have a predetermined thickness from a top surface of the semiconductor pattern and includes a metal layer including the reduced metal.

A second insulation layer 50 may cover the semiconductor pattern of the third transistor T3 and be disposed on the first insulation layer 40. In an embodiment, the second insulation layer 50 may include a silicon oxide layer and a silicon nitride layer. The second insulation layer 50 may include a plurality of silicon oxide layers and a plurality of silicon nitride layers, which are alternately laminated with each other.

The gate G3 of the third transistor T3 may be disposed on the second insulation layer 50. The gate G3 may be a portion of a metal pattern. The gate G3 of the third transistor T3 overlaps the active A3 of the third transistor T3.

In an embodiment, the second insulation layer 50 may be disposed over the entire active area AA as shown in FIG. 6, but the embodiment of the invention is not limited thereto. In an alternative embodiment, for example, the second insulation layer 50 may be replaced by an insulation pattern. The gate G3 of the third transistor T3 is disposed on the insulation pattern. In such an embodiment, the gate G3 may have a same shape as the insulation pattern on the plane.

A third insulation layer 60 may cover the gate G3 and be disposed on the second insulation layer 50. In an embodiment, the third insulation layer 60 may include a silicon oxide layer and a silicon nitride layer. The third insulation layer 60 may include a plurality of silicon oxide layers and a plurality of silicon nitride layers, which are alternately laminated with each other.

According to an embodiment, the source S4 and the drain D4 of the fourth transistor T4 (refer to FIG. 3) may be provided through a same process as the source S3 and the drain D3 of the third transistor T3, and the gate G4 of the fourth transistor T4 (refer to FIG. 3) may be provided through a same process as gate G3 of the third transistor T3.

At least one insulation layer may be further disposed on the third insulation layer 60. In an embodiment, an organic layer 71 and an upper organic layer 72 may be disposed on the third insulation layer 60. Each of the organic layer 71 and the upper organic layer 72 may include an organic material. In an embodiment, for example, each of the organic layer 71 and the upper organic layer 72 may include a polyimide-based resin. However, the embodiment of the invention is not limited thereto. In an alternative embodiment, for example, each of the organic layer 71 and the upper organic layer 72 may include at least one selected from an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin.

A first connection electrode CNE1 may be disposed on the third insulation layer 60. The first connection electrode CNE1 may be connected to the connection signal line SCL through a first contact hole CHI defined through the first to third lower insulation layers 10 to 30 and the first to third insulation layers 40 to 60. The first connection electrode CNE1 according to an embodiment may be connected to conductive patterns disposed in a same layer as the semiconductor pattern of the first transistor T1. However, the embodiment of the invention is not limited thereto.

The organic layer 71 may cover the first connection electrode CNE1 and be disposed on the third insulation layer 60.

A second connection electrode CNE2 may be disposed on the organic layer 71. The second connection electrode CNE2 is connected to the first connection electrode CNE1 through a second contact hole CH-71 defined through the organic layer 71.

The upper organic layer 72 may cover the second connection electrode CNE2 and be disposed on the organic layer 71. The light emitting element OLED may be connected to the second connection electrode CNE2 through a third contact hole CH-72 defined through the upper organic layer 72. However, the embodiment of the invention is not limited thereto.

Components of the light emitting element OLED may be disposed on the upper organic layer 72. The light emitting element OLED may include a first electrode AE, a hole control layer HCL, a light emitting layer EML, an electron control layer ECL, and a second electrode CE. The pixel defining layer PDL is disposed on the upper organic layer 72. An opening D-OP exposing at least a portion of the first electrode AE may be defined in the pixel defining layer PDL. In an embodiment, the pixel defining layer PDL may have a predetermined color and include a light absorbing material. In an embodiment, for example, the pixel defining layer PDL may have a black color.

The first to seventh transistors TI to T7 (refer to FIG. 4) may constitute one pixel circuit PDC (refer to FIG. 4), and the pixel circuit PDC (refer to FIG. 4) may be connected with the light emitting element OLED to constitute one pixel PXij (refer to FIG. 4).

The opening OP of the pixel defining layer PDL may define a light emitting area. In an embodiment, for example, a plurality of pixels PXij (refer to FIG. 4) may be arranged on a plane of the display panel DP under a predetermined rule. An area on which the plurality of pixels PXij (refer to FIG. 4) are arranged may be defined as the active area AA (refer to FIG. 1A), and the active area AA may include a plurality of light emitting areas and a non-light emitting area disposed adjacent to the light emitting areas. The non-light emitting area may be defined by the pixel defining layer PDL and surround the light emitting area defined by the opening OP of the pixel defining layer PDL.

The first electrode AE may be disposed on the upper organic layer 72. The first electrode AE is connected to the second connection electrode CNE2 through the third contact hole CH-72 defined through the upper organic layer 72. The hole control layer HCL may be disposed on the first electrode AE.

The hole control layer HCL may be disposed on the light emitting area and the non-light emitting area in common. A common layer such as the hole control layer HCL and the electron control layer ECL may be provided to the plurality of pixels PXij in common. The hole control layer HCL may include a hole transport layer and a hole injection layer.

The light emitting layer EML may be disposed on the hole control layer HCL. The light emitting layer EML may overlap the opening OP. The light emitting layer EML may be divided and provided on each of the plurality of pixels PXij.

In an embodiment, the light emitting layer EML may be patterned to be divided as shown in FIG. 6, but not being limited thereto. Alternatively, the light emitting layer EML may be disposed on the plurality of pixels PXij in common. In such an embodiment, the light emitting layer EML may generate white light or blue light. Also, the light emitting layer EML may have a multi-layer structure.

The electron control layer ECL may be disposed on the light emitting layer EML. The electron control layer ECL may include an electron transport layer and an electron injection layer. The second electrode CE may be disposed on the electron control layer ECL. The electron control layer ECL and the second electrode CE may be disposed on the plurality of pixels PXij in common.

The encapsulation layer TFE may be disposed on the second electrode CE. The encapsulation layer TFE may be disposed on the plurality of pixels PXij in common. In an embodiment, the encapsulation layer TFE directly covers the second electrode CE. The encapsulation layer TFE may include a first thin-film inorganic layer 81, a thin-film organic layer 82, and a second thin-film inorganic layer 83. However, the embodiment of the invention is not limited thereto. In an alternative embodiment, for example, the encapsulation layer TFE may further include a plurality of inorganic layers and a plurality of organic layers.

The first thin-film inorganic layer 81 may contact the second electrode CE. The first thin-film inorganic layer 81 may prevent external moisture or oxygen from being permeated into the light emitting layer EML. In an embodiment, for example, the first thin-film inorganic layer 81 may include a silicon nitride, a silicon oxide, or a combination thereof. The first thin-film inorganic layer 81 may be provided through a deposition process.

The thin-film organic layer 82 may be disposed on the first thin-film inorganic layer 81 to contact the first thin-film inorganic layer 81. The thin-film organic layer 82 may provide a flat surface on the first thin-film inorganic layer 81. The thin-film organic layer 82 may cover curvedness (or unevenness) of a top surface of the first thin-film inorganic layer 81 or particles existing on the first thin-film inorganic layer 81 to prevent a surface state of the top surface of the first thin-film inorganic layer 81 from affecting components provided on the thin-film organic layer 82. The thin-film organic layer 82 may include an organic material and be provided through a solution process such as spin coating, slit coating, and an inkjet process.

The second thin-film inorganic layer 83 may be disposed on the thin-film organic layer 82 to cover the thin-film organic layer 82. The second thin-film inorganic layer 83 may be relatively stably provided on the flat surface than being disposed on the first thin-film inorganic layer 81. The second thin-film inorganic layer 83 may prevent moisture or oxygen from being introduced into the light emitting layer EML. The second thin-film inorganic layer 83 may include a silicon nitride, a silicon oxide, or a combination thereof. The second thin-film inorganic layer 83 may be provided through a deposition process.

The input sensing layer ISL may be provided directly on the encapsulation layer TFE. The input sensing layer ISL may include a plurality of conductive patterns MS1 and MS2 and sensing insulation layers. The sensing insulation layers may include a first sensing insulation layer 91, a second sensing insulation layer 92, and a third sensing insulation layer 93.

The first sensing insulation layer 91 may be disposed on the encapsulation layer TFE. The first conductive patterns MS1 may be disposed on the first sensing insulation layer 91 and covered by the second sensing insulation layer 92. The second conductive patterns MS2 may be disposed on the second sensing insulation layer 92 and covered by the third sensing insulation layer 93.

Each of the conductive patterns MS1 and MS2 has high conductivity. Each of the conductive patterns MS1 and MS2 may have a single-layer structure or a multi-layer structure. However, the embodiment of the invention is not limited thereto. At least one conductive patterns of the conductive patterns MS1 and MS2 according to an embodiment of the invention may be provided as mesh lines on the plane.

The mesh lines of the conductive patterns MS1 and MS2 may overlap the pixel defining layer PDL on the plane. Thus, although the input sensing layer ISL is provided directly on the display panel DP, light provided from the pixels PXij (refer to FIG. 4) of the display panel DP may be provided to a user without interference.

The filter layer CFL may include a color filter 100, a black matrix BM, and an overcoat layer OC.

The color filter 100 may include a polymer photosensitive resin and a pigment or a dye. In an embodiment, for example, the color filter 100 for providing blue light and overlapping the light emitting layer EML may include a blue pigment or dye, the color filter 100 for providing green light and overlapping the light emitting layer EML may include a green pigment or dye, and the color filter 100 for providing red light and overlapping the light emitting layer EML may include a red pigment or dye.

However, the embodiment of the invention is not limited thereto. In an alternative embodiment, for example, the color filter 100 overlapping the light emitting layer EML may not include a pigment or a dye. In such an embodiment, the color filter 100 may be transparent and include or made of a transparent photosensitive resin.

The black matrix BM may be disposed between the color filters for providing different colors. The black matrix BM may be a pattern having a black color and a grid-type matrix. The black matrix BM may include a black coloring agent. The black coloring agent may include a black pigment and a black dye. The black coloring agent may include metal such as chrome and carbon black or an oxide thereof.

The overcoat layer OC may be disposed on the color filter 100 and the black matrix BM. The overcoat layer OC may be a layer surrounding an unevenness generated in a process of providing the color filter 100 and the black matrix BM and providing a flat surface. That is, the overcoat layer OC may be a planarization layer. The window WM described in FIG. 2 may be coupled with the overcoat layer OC by an adhesive layer AL.

A boundary hole VA-H formed by removing at least a portion of the first to third lower insulation layers 10 to 30 and the first to third insulation layers 40 to 60 may be defined in the circuit layer DP-CL according to an embodiment of the invention.

The boundary hole VA-H may be defined or formed through at least a portion of the insulation layers 10 to 60 from the third insulation layer 60. In an embodiment, for example, the boundary hole VA-H may extend from the third insulation layer 60 to the first lower insulation layer 10 disposed on the buffer layer BFL. Alternatively, in an embodiment, the boundary hole VA-H may be defined only in the third insulation layer 60 disposed below the organic layer 71. Thus, at least a portion of the insulation layers 10 to 60 may be defined in a floating state. The floating state may be defined as a state of being electrically insulated in addition to a state of being disconnected in an island shape. According to an embodiment of the invention, the boundary hole VA-H may individually disconnect the insulation layers 10 to 60 to prevent an external impact or a crack from being transmitted to the pixel circuit units PDU1 and PDU2 (refer to FIG. 5) through the insulation layers 10 to 60. Thus, the display device DD (refer to FIG. 1A) having improved durability may be provided.

The boundary hole VA-H may overlap only the boundary area OA. The boundary hole VA-H may not overlap the pixel area PA. The boundary hole VA-H may include a first boundary hole VA-H1 and a second boundary hole VA-H2. The boundary area OA may include a first boundary area OA1 and a second boundary area OA2. The first boundary hole VA-H1 may overlap the first boundary area OA1 of the boundary area OA. The second boundary hole VA-H2 may overlap the second boundary area OA2 of the boundary area OA. The first boundary hole VA-H1 and the second boundary hole VA-H2 may define the first boundary area OA1 and the second boundary area OA2, respectively. In this specification, the second boundary hole VA-H2 may be defined as a “valley hole”.

The circuit layer DP-CL according to an embodiment may include a line layer ON and a valley electrode VA-G disposed on one random insulation layer among the insulation layers 10 to 60. In an embodiment, for example, the line layer ON may be disposed on the first insulation layer 40. The second insulation layer 50 may be disposed on the line layer ON, and the valley electrode VA-G may be disposed on the second insulation layer 50. The valley electrode VA-G may be disposed in or directly on a same layer as the above-described gate G3. The valley electrode VA-G may include a same material and be provided through a same process as the above-described gate G3. A line contact hole G-CH may be defined in the second insulation layer 50 to electrically connect the line layer ON and the valley electrode VA-G. The third insulation layer 60 may be disposed on the valley electrode VA-G, and a valley hole VA-H2 may be defined in the third insulation layer 60. At least a portion of the organic layer 71 may be filled into the valley hole VA-H2. The line layer ON, the valley electrode VA-G, and the valley hole VA-H2 may overlap the second boundary area OA2. This will hereinafter be described in greater detail.

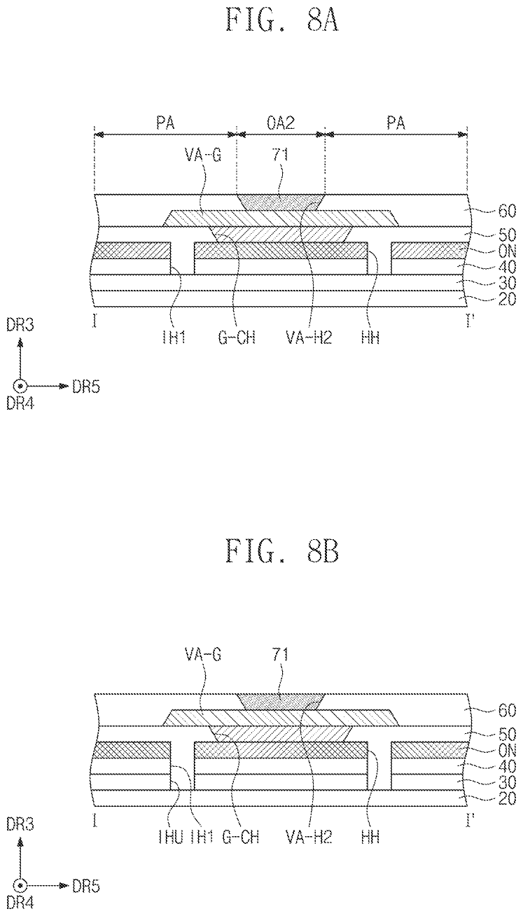

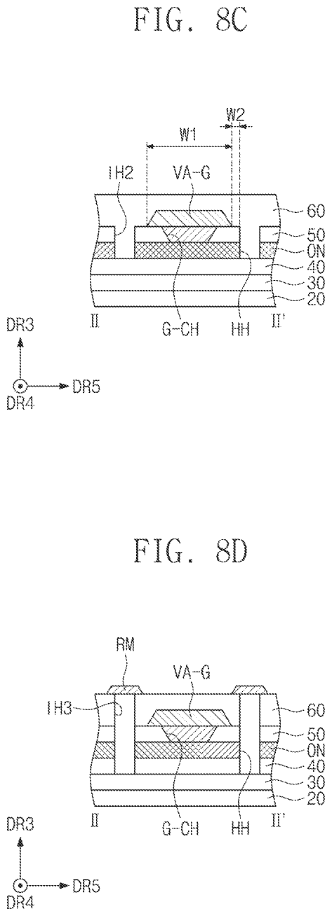

FIGS. 7A and 7B are plan views illustrating some of components contained in a display module according to embodiments of the invention. FIGS. 8A to 8D are cross-sectional views illustrating some of the components contained in the display module according to embodiments of the invention. FIGS. 8A and 8B are cross-sectional views taken along line I-I′ of FIG. 7A according to embodiments of the invention. FIGS. 8C and 8D are cross-sectional views taken along line II-II′ of FIG. 7B according to embodiments of the invention. FIGS. 7A and 7B and FIGS. 8A to 8D illustrate a plane or a cross-section of one portion of the display module corresponding to the second boundary area OA2 and the pixel area PA adjacent to the second boundary area OA2 described in FIG. 6. The same or similar components as those described in FIGS. 1A to 6 will be designated by the same or similar reference numerals, respectively, and any repetitive detailed description thereof will be omitted.

Referring to FIGS. 8A to 8D, the line layer ON according to an embodiment may be disposed on one insulation layer among the insulation layers 20 to 60. In an embodiment, for example, the line layer ON may be disposed on the first insulation layer 40.

The line layer ON includes at least one selected from zinc (Zn), indium (In), gallium (Ga), tin (Sn), and titanium (Ti). In an embodiment, the line layer ON may include metal reduced from a metal oxide semiconductor. The line layer ON may include only metal instead of a metal oxide semiconductor. That is, the line layer ON may include metal reduced from one selected from an indium-tin oxide (ITO), an indium-gallium-zinc oxide (IGZO), a zinc oxide (ZnO), an indium-zinc oxide (IZnO), a zinc-indium oxide (ZIO), an indium oxide (InO), a titanium oxide (TiO), an indium-zinc-tin oxide (IZTO), and a zinc-tin oxide (ZTO).

Referring to FIGS. 7A, 7B, and 8A to 8D, at least one line hole HH may be defined in the line layer ON. The line hole HH may expose an inner surface of at least a portion of the line layer ON. The line hole HH may be formed through at least a portion of the line layer ON. As the line hole HH is defined in the line layer ON, an area excluding zinc (Zn), indium (In), gallium (Ga), tin (Sn), and titanium (Ti) may be defined in the line layer ON.

In an embodiment, insulation hole IH1 to IH3 and IHU may be defined in the one insulation layer among the insulation layers 10 to 60. The insulation hole IH1 to IH3 and IHU may expose an inner surface of the one insulation layer among the insulation layers 10 to 60 or extend through the one insulation layer among the insulation layers 10 to 60. The insulation hole IH1 to IH3 and IHU may be defined to correspond to (or overlap or be aligned with) the line hole HH. The insulation hole IH1 to IH3 and IHU and the line hole HH may be substantially one hole. That is, the insulation hole IH1 to IH3 and IHU may extend from the line hole HH in the third direction DR3 or in a direction opposite to the third direction DR3.

Referring to FIGS. 8A to 8C, one insulation layer disposed on the line layer ON among the insulation layers 20 to 60 may be filled in the line hole HH. In an embodiment, for example, a portion of the second insulation layer 50 or the third insulation layer 60 may be disposed in the line hole HH. Each of the insulation layers 20 to 60 may include at least one selected from aluminum oxide, titanium oxide, silicon oxide, silicon nitride, silicon oxynitride, zirconium oxide, and hafnium oxide. A specific amount of hydrogen may be provided in the insulation layers 20 to 60 by a deposition process when the display panel according to an embodiment of the invention is manufactured. Thus, each of the insulation layers 20 to 60 may contain a specific amount of hydrogen in the thin-film. Thus, the line layer ON according to an embodiment of the invention may include metal reduced through hydrogen introduced into the line hole HH. That is, in an embodiment of the invention, at least a portion of the line layer ON may be metal reduced through hydrogen introduced into the line hole HH when the display panel is manufactured.

Referring to FIG. 8D, a specific inorganic material or organic material may not be disposed in the line hole HH according to an embodiment. The line layer ON according to an embodiment of the invention may include metal reduced by diffusion of hydrogen contained in the one insulation layer among the insulation layers 20 to 60. A roof electrode RM may be disposed on the line hole HH. In an embodiment, for example, where the third insulation hole IH3 is defined in the third insulation layer 60, the roof electrode RM may be disposed on the third insulation layer 60 and cover the line hole HH. Thus, a specific material may not be disposed in the line hole HH although the organic layer 71 is additionally disposed on the line hole HH. However, this is merely illustrative, and the roof electrode RM may have various arrangement structures such as being disposed on the organic layer 71 (refer to FIG. 8A) as desired.

Referring to FIGS. 7A, 8A, and 8B, the line hole HH may overlap the valley electrode VA-G on the plane. The line hole HH may be provided in a same process as the line layer ON. The line hole HH may be provided before the valley electrode VA-G is provided. However, this is merely illustrative, and the line hole HH may be provided in a random process as necessary among processes of manufacturing the display device according to an embodiment of the invention.

Referring to FIG. 8A, in an embodiment, a first insulation hole IH1 may be defined in the first insulation layer 40. The first insulation hole IH1 may be defined to correspond to (or overlap or be aligned with) the line hole HH. Referring to FIG. 8B, in an alternative embodiment, the first insulation hole IH1 may be defined in the first insulation layer 40, and a lower insulation hole IHU may be defined in the third lower insulation layer 30. The line hole HH, the first insulation hole IH1, and the lower insulation hole IHU may be defined to correspond to (or overlap or be aligned with) each other. That is, in such an embodiment, one hole defined through the line layer ON to the first insulation layer 40 or through the line layer ON to the third lower insulation layer 30 may be defined.

Referring to FIGS. 7B, 8C, and 8D, the line hole HH may be spaced apart from the valley electrode VA-G on the plane. The line hole HH may be provided after a process of providing the line layer ON. In an embodiment, for example, the line hole HH may be provided after a process of providing the second insulation layer 50 or after a process of providing the third insulation layer 60. However, this is merely illustrative, and the line hole HH may be provided in any process as desired among the processes of manufacturing the display device according to an embodiment of the invention.

Referring to FIGS. 7B and 8C, the line hole HH may not overlap the valley electrode VA-G on the plane. The line hole HH may be defined in an area adjacent to the valley electrode VA-G on the plane. Specifically, the line hole HH may be adjacent to the valley electrode VA-G in a first horizontal direction DR4 and a second horizontal direction DR5. In this specification, the first horizontal direction DR4 may be defined as a direction in which the valley hole VA-H2 extends, and the second horizontal direction DR5 may be a direction crossing the first horizontal direction DR4. Each of the first horizontal direction DR4 and the second horizontal direction DR5 may be perpendicular to the third direction DR3.

Referring to FIG. 8C, a first width W1 may be defined as a width of the valley electrode VA-G in the first horizontal direction DR4, and a first distance W2 may be defined as a minimum distance from the line hole HH to the valley electrode VA-G in the first horizontal direction DR4. In an embodiment, the first distance W2 may be less than the first width W1. Thus, as the line hole HH is defined in the area adjacent to the valley electrode VA-G, the hydrogen introduced into the line hole HH may be diffused to the valley electrode VA-G.

Referring to FIG. 8C, a second insulation hole IH2 may be defined in the second insulation layer 50. The second insulation hole IH2 may be defined to correspond to (or overlap or be aligned with) the line hole HH. Referring to FIG. 8D, the second insulation hole IH2 may be defined in the second insulation layer 50, and a third insulation hole IH3 may be defined in the third insulation layer 60. The line hole HH, the second insulation hole IH2, and the third insulation hole IH3 may be defined to correspond to (or overlap or be aligned with) each other.

Referring to FIGS. 7A, 7B, and 8A to 8D, a plurality of line holes HH according to an embodiment may be defined in the line layer ON. In an embodiment, for example, two or four or more line holes HH may be provided. The plurality of line holes HH according to an embodiment may be symmetric with respect to the second horizontal direction DR5 based on the valley electrode VA-G. Thus, a content of reduced metal in the line layer ON according to an embodiment may increase.

The valley electrode VA-G according to an embodiment may be disposed on one insulation layer among the insulation layers 10 to 60. In an embodiment, for example, the second insulation layer 50 may cover the line layer ON, and the valley electrode VA-G may be disposed on the second insulation layer 50. The valley electrode VA-G may overlap the second boundary area OA2.

Although a process of providing the valley hole VA-H2 in the processes of manufacturing the display device according to an embodiment of the invention includes an etching process such as etching, the line layer ON overlapping a second boundary area OA2 may not be etched by using the valley electrode VA-G as a roof. Thus, as the valley electrode VA-G is disposed on the line layer ON in the second boundary area OA2, a current flow of the line layer ON may be maintained although the valley hole VA-H2 is provided.

A line contact hole G-CH for electrically connecting the line layer ON and the valley electrode VA-G according to an embodiment may be defined in one random insulation layer among the insulation layers 10 to 60. In an embodiment, for example, the second insulation layer 50 may cover the line layer ON, and the line contact hole G-CH may be defined in the second insulation layer 50. The line contact hole G-CH may not overlap the line hole HH on the plane. The line contact hole G-CH may expose a portion of the line layer ON. A partial area of the line layer ON, which is exposed by the line contact hole G-CH and electrically connected with the valley electrode VA-G, may include reduced metal although the line hole HH is not defined.

The valley hole VA-H2 may be defined in the third insulation layer 60. In an embodiment, the third insulation layer 60 may cover the valley electrode VA-G, and the valley hole VA-H2 may be defined in the third insulation layer 60 to overlap the second boundary area OA2. The valley hole VA-H2 may have a structure extending in the first horizontal direction DR4. At least a portion of the organic layer 71 may be disposed in the valley hole VA-H2. That is, the organic layer 71 may fill the valley hole VA-H2. Thus, an external impact or a crack may be prevented from being transmitted to the pixel circuit units PDU1 and PDU2 (refer to FIG. 5), and the display device DD (refer to FIG. 1A) having improved durability may be provided.

The display device according to an embodiment of the invention includes the valley electrode disposed on the line layer, and the valley hole is defined on the valley electrode. The process of providing the valley hole according to an embodiment of the invention includes the etching process. In such an embodiment, the line layer may not be etched by using the valley electrode as a roof. In such an embodiment, the line hole may be defined in the line layer. Accordingly, the hydrogen contained in the insulation layer may induce reduction of the line layer through the line hole, and the line layer may become conductive, thereby functioning as a conductor. Thus, the display device according to an embodiment of the invention may provide the valley hole even in the area on which the line layer is disposed to have further improved durability.

According to an embodiment of the invention, as the valley hole for allowing the inorganic layers to be disconnected is provided, the external impact or the crack may be effectively prevented from being transmitted to the pixel circuit through the inorganic layers. Thus, the display device having improved durability may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a base layer;
a first insulation layer disposed on the base layer;
a line layer disposed on the first insulation layer, wherein the line layer comprises at least one selected from zinc (Zn), indium (In), gallium (Ga), tin (Sn) and titanium (Ti), and a line hole is defined in the line layer,
a second insulation layer disposed on the line layer, wherein a line contact hole is defined in the second insulation layer,
a valley electrode disposed on the second insulation layer and electrically connected with the line layer through the line contact hole;
a third insulation layer disposed on the valley electrode, wherein a valley hole is defined in the third insulation layer; and
an organic layer disposed on the third insulation layer,
wherein the line hole is defined through at least a portion of the line layer, and
at least a portion of the organic layer is disposed in the valley hole to contact the valley electrode.

2. The display device of claim 1, wherein the valley hole overlaps the valley electrode on a plane.

3. The display device of claim 1, wherein the line hole is spaced apart from the line contact hole on a plane.

4. The display device of claim 1, wherein at least a portion of the first insulation layer, the second insulation layer, and the third insulation layer is disposed in the line hole.

5. The display device of claim 1, wherein the line hole is provided in plurality.

6. The display device of claim 5, wherein
the valley hole extends in a first horizontal direction, and
a plurality of line holes is symmetric in a second horizontal direction crossing the first horizontal direction with respect to the valley electrode.

7. The display device of claim 1, wherein the line hole overlaps the valley electrode on a plane.

8. The display device of claim 1, wherein the line hole is spaced apart from the valley electrode on a plane.

9. The display device of claim 8, wherein
the valley hole extends in a first horizontal direction, and
a distance from the valley electrode to the line hole in the first horizontal direction is less than a width of the valley electrode in the first horizontal direction on a plane.

10. The display device of claim 1, wherein
a first insulation hole is defined in the first insulation layer, and
the first insulation hole is defined to correspond to the line hole on a plane.

11. The display device of claim 1, wherein
a second insulation hole is defined in the second insulation layer, and
the second insulation hole is defined to correspond to the line hole on a plane.

12. The display device of claim 1, wherein each of the first insulation layer, the second insulation layer, and the third insulation layer comprises at least one selected from an aluminum oxide, a titanium oxide, a silicon oxide, a silicon nitride, a silicon oxynitride, a zirconium oxide, and a hafnium oxide.

13. The display device of claim 1, further comprising:
a plurality of lower insulation layers disposed below the first insulation layer,
wherein the plurality of lower insulation layers comprises a first lower insulation layer, a second lower insulation layer, and a third lower insulation layer, which are sequentially laminated on the base layer.

14. The display device of claim 13, wherein
a lower insulation hole is defined in the third lower insulation layer, and
the line hole is defined to correspond to the lower insulation hole on a plane.

15. The display device of claim 13, further comprising:
a first transistor disposed on the first lower insulation layer,
wherein the first transistor comprises a silicon semiconductor pattern.

16. The display device of claim 1, further comprising:
a second transistor disposed on the first insulation layer,
wherein the second transistor comprises an oxide semiconductor pattern.

17. The display device of claim 16, wherein
the second transistor further comprises an oxide gate, and
the oxide gate is disposed on the second insulation layer.

18. The display device of claim 17, wherein a material included in the oxide gate is the same as a material included in the valley electrode.

19. The display device of claim 16, wherein the oxide semiconductor pattern comprises at least one selected from an indium-tin oxide (ITO), an indium-gallium-zinc oxide (IGZO), an zinc oxide (ZnO), an indium-zinc oxide (IZnO), a zinc-indium oxide (ZIO), an indium oxide (InO), a titanium oxide (TiO), an indium-zinc-tin oxide (IZTO), and a zinc-tin oxide (ZTO).

20. A display device comprising:
a base layer;
a plurality of insulation layers disposed on the base layer; and
a line layer disposed between the plurality of insulation layers, wherein a line hole is defined in the line layer,
wherein the line layer comprises at least one selected from zinc (Zn), indium (In), gallium (Ga), tin (Sn), and titanium (Ti),
the line hole is defined by an inner surface of the line layer, and
a portion an insulation layer among the plurality of insulation layers is disposed in the line hole.
